(19) United States
(12) Patent Application Publication
(10) Pub. No.: US 2026/0239651 A1
(43) Pub. Date: Aug. 13, 2026

(54) HIGH STABILITY GaN DEVICE AND GaN BRIDGE INTEGRATED CIRCUIT

(71) Applicant: Peking University, Beijing (CN)

(72) Inventors: Jin WEI, Beijing (CN); Junjie Yang, Beijing (CN)

(73) Assignee: Peking University, Beijing (CN)

(21) Appl. No.: 19/181,372

(22) Filed: Apr. 17, 2025

Related U.S. Application Data
(63) Continuation of application No. PCT/CN2023/131353, filed on Nov. 13, 2023.

(30) Foreign Application Priority Data
Nov. 14, 2022 (CN) 202211417832.4

(51) Int. Cl. H10D 30/47; H10D 62/852

(52) U.S. Cl. CPC H10D 30/472; H10D 62/852

(57) ABSTRACT

The present disclosure discloses a high stability GaN device and a GaN bridge integrated circuit. The GaN device include: a substrate; and a transition layer, a buffer layer, a hole blocking layer, a channel layer, and a barrier layer sequentially stacked on the substrate; a source and a drain of the GaN device disposed in an active region above the barrier layer; a gate of the GaN device located between the source and the drain; and a hole injection layer formed between the gate and the barrier layer, wherein the hole blocking layer is inserted between the channel layer and the buffer layer and the top of a valence band of the hole barrier layer is lower than the top of a valence band of the channel layer.

### CROSS REFERENCE TO RELATED APPLICATIONS

The present application is a continuation of International Application No. PCT/CN2023/131353, filed on Nov. 13, 2023, which claims priority to Chinese patent application No. 202211417832.4, filed on Nov. 14, 2022 and entitled with “High Stability GaN Device and GaN Bridge Integrated Circuit”, both of which are incorporated herein by reference in their entireties.

### TECHNICAL FIELD

The present disclosure relates to the field of power and electronic devices, in particular to a high stability GaN device and a GaN bridge integrated circuit.

### BACKGROUND

In a GaN device, a two-dimensional electron gas channel with high electron mobility may be formed between a barrier layer and a channel layer through polarization effects, such that the GaN power device can achieve a lower on-resistance and a higher operation frequency. However, after the GaN power device experiences a high drain voltage during an off-state, negative charges will accumulate in a buffer layer, leading to an increase in the device's conduction resistance, which results in current collapse effects. Moreover, parasitic effects of discrete devices during interconnection may limit the operating frequency of the GaN device. By integrating GaN power devices on a single chip, operating frequency of the circuit can be further improved. However, in a traditional GaN-on-Si epitaxy platform, such single chip integration may be limited by substrate-induced crosstalk effects (back-gating effects) which can lead to severe degradation of the device's conduction characteristics.

So far, a drain technology combining p-GaN and an ohmic electrode has been proposed (H. Okita, M. Hikita, A. Nishio, T. Sato, K. Matsunaga, H. Matsuo, M. Mannoh, and Y. Uemoto, “Through recessed and regrowth gate technology for realizing process stability of GaN-GITs”, in Proc. ISPSD, Prague, Czech Republic, June 2016, pp. 23-26), which can suppress the current collapse effects by injecting holes on a drain side of an involved device during an off-state. However, the device requires a GaN regrowth process, which is complex and costly.

Furthermore, a GaN-on-SOI technology has been proposed (T. Cosnier et al., “200 V GaN-on-SOI Smart Power Platform for Monolithic GaN Power ICs”, IEEE International Electron Devices Meeting (IEDM), 2021, pp. 5.1.1-5.1.4), which can suppress the substrate-induced crosstalk effects by insulation properties of an oxide layer. However, the silicon-on-insulator (SOI) technology is still complex and costly.

### SUMMARY

In an aspect, the embodiments of the present disclose provides a GaN device, comprising: a substrate; and a transition layer, a buffer layer, a hole blocking layer, a channel layer, and a barrier layer sequentially stacked on the substrate; a source and a drain of the GaN device disposed in an active region above the barrier layer; a gate of the GaN device located between the source and the drain; and a hole injection layer formed between the gate and the barrier layer, wherein the hole blocking layer is inserted between the channel layer and the buffer layer and the top of a valence band of the hole barrier layer is lower than the top of a valence band of the channel layer.

In another aspect, the embodiments of the present disclose provides a GaN bridge integrated circuit, comprising: two GaN transistors that share a common substrate, one of which serves as an upper transistor and the other serves as a low-side transistor, wherein a source of the upper transistor is connected to a drain of the lower transistor, wherein the substrate is configured by one of the followings: being floating, including an ohmic contact electrode located on the back of the substrate and connected to a source of the low-side transistor, or including an ohmic contact electrode located on the back of the substrate and connected to the source of the upper transistor, and wherein each of the upper transistor and the low-side transistor comprises: a transition layer, a buffer layer, a hole blocking layer, a channel layer, and a barrier layer sequentially stacked on the substrate; a source and a drain of the GaN transistor disposed in an active region above the barrier layer; a gate of the GaN transistor located between the source and the drain; and a hole injection layer formed between the gate and the barrier layer, wherein the hole blocking layer is inserted between the channel layer and the buffer layer and the top of a valence band of the hole barrier layer is lower than the top of a valence band of the channel layer.

### BRIEF DESCRIPTION OF THE DRAWINGS

FIG. 1 is a two-dimensional cross-sectional view of a GaN device according to an embodiment of the present disclosure.

FIG. 2 illustrates basic principles of the GaN device suppressing current collapse effects and substrate-induced crosstalk effects.

FIG. 3 illustrates test results of conduction characteristics of the GaN device as a function of substrate voltage.

FIG. 4 is a two-dimensional cross-sectional view of a GaN bridge integrated circuit according to an embodiment of the present disclosure.

FIG. 5 is a two-dimensional cross-sectional view of a GaN bridge integrated circuit according to an embodiment of the present disclosure.

FIG. 6 is a two-dimensional cross-sectional view of a GaN bridge integrated circuit according to an embodiment of the present disclosure.

### DETAILED DESCRIPTION

The technical solutions of the present disclosure will be described in detail below by reference to embodiments in conjunction with accompanying drawings, which does not limit scope of the present disclosure in any way.

In order to achieve a high-stability GaN device with suppressed current collapse effects, the present disclosure proposes a new GaN device structure which realizes suppression of the current collapse effects. Also, the device realizes suppression of the substrate-induced crosstalk effects. Based on the device proposed according to the present disclosure, a new GaN device and GaN bridge integrated circuit is demonstrated for monolithically integrated half-bridge circuit.

The GaN device according to the present disclosure is based on a traditional enhanced GaN power HEMT structure, and is designed by additionally inserting a hole blocking layer between a channel layer and a buffer layer, with which an additional hole spreading layer is formed between the channel layer and the hole blocking layer.

The hole blocking layer may include a material selected from one or more of AlGaN, AlN, InN, or AlInGaN. The hole blocking layer may be prepared by metal organic chemical vapor deposition (MOCVD) during epitaxial growth. A thickness of the hole blocking layer may range from 1 nm to 100 nm, preferably 15 nm to 25 nm. In view of the energy band, the top of a valence band of the hole blocking layer is lower than that of the channel layer, which can prevent hole injection into the substrate. Due to the insertion of the hole blocking layer between the channel layer and the buffer layer, when a positive bias is applied to the gate and source, the hole injection layer will inject holes into the hole blocking layer and the injected holes would spread above the hole blocking layer. Therefore, a conductive hole spreading layer is formed on the top surface of the hole blocking layer. It is worthy noted that the hole spreading layer is an energy well for holes, due to the energy offset and polarization effects. At zero-bias condition (e.g. without hole injection), although no hole exists in the interface of channel layer and hole blocking layer, the injected holes from hole injection layer could spread along the hole blocking layer, forming a conductive hole spreading channel with mobile holes. For other condition, if there are holes initially exists in the interface of channel layer and hole blocking layer, the screening effect on buffer trapping and substrate-induced crosstalk is not available, unless conductive hole spreading channel formed with hole injection from hole injection layer.

The technical solutions of the present disclosure are described as follows.

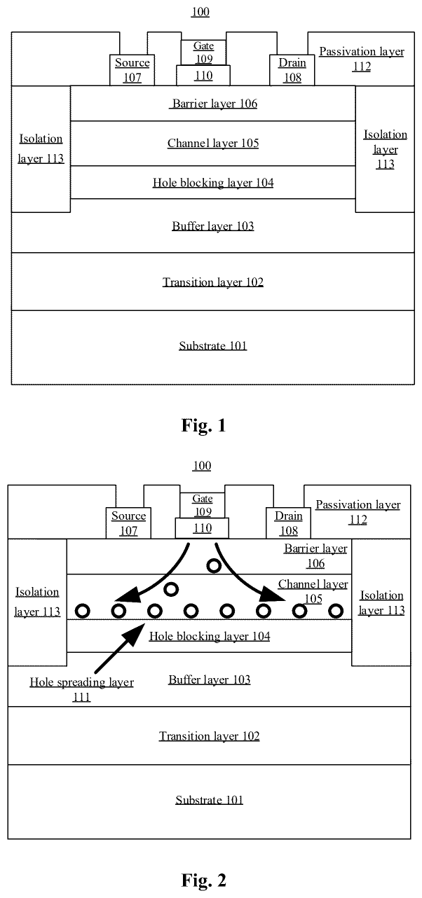

FIG. 1 is a two-dimensional cross-sectional view of a GaN device according to an embodiment of the present disclosure. As shown in FIG. 1, a typical GaN device 100 according to the present disclosure includes a substrate 101 and a transition layer 102, the buffer layer 103, a hole blocking layer 104, a channel layer 105, and a barrier layer 106 sequentially stacked on the substrate 101, a source 107 and a drain 108 of the GaN device are disposed in an active region above the barrier layer 106, a gate 109 of the GaN device is located between the source 107 and the drain 108, and a hole injection layer 110 is formed between the gate 109 and the barrier layer 106, wherein the hole blocking layer 104 is inserted between the channel layer 105 and the buffer layer 103. The top of a valence band of the hole barrier layer 104 is lower than the top of a valence band of the channel layer 105.

As shown in FIG. 1, the substrate 101 may include one or more of a silicon substrate, a sapphire substrate, AlN substrate, or SiC substrate, or the like. The transition layer 102 is provided to balance lattice and stress mismatch in epitaxy, and may include AlN, GaN, or a combination thereof. The buffer layer 103 is provided to reduce leakage current of the device during an off-state and increase a breakdown voltage of the device. The buffer layer 103 is a high resistance layer and may be doped with carbon or iron. The buffer layer 103 may include a material selected from AlN, GaN, or a combination thereof. The hole blocking layer 110 may include at least one of AlGaN, AlN, InN, or AlInGaN, or a combination thereof. In view of the energy band, the top of a valence band of the hole blocking layer 104 is lower than that of the channel layer 105. The channel layer 105 provides a conductive channel for two-dimensional electron gas, and may include a material selected from GaN, AlGaN, InN, or AlInGaN, etc. The barrier layer 106 may include a material selected from at least one of AlGaN, AlN, InN, or AlInGaN, or a combination thereof, and is provided to provide two-dimensional electron gas through polarization effects. The source 107 and the drain 108 of the GaN device are prepared using ohmic contacts at both sides of the gate 109 of the GaN device, the gate 109 being disposed above the hole injection layer 110. With existing preparation processes, the hole injection layer 110 may include a P-type doped semiconductor, which may be a P-type doped GaN, AlGaN, AlN, or InN, etc.

In some embodiments, as shown in FIG. 1, the GaN device 100 according to the present disclosure may include a passivation layer 112, an isolation layer 113 and in some embodiments, it may include a field plate included in a traditional high electron mobility transistor (HEMT) device. The passivation layer 112 may include a material selected from at least one of Al₂O₃, SiO₂, SiN, AlN, HfO₂, or other dielectric materials. The isolation layer 113 may be formed by etching isolation, injection isolation, or the both, and the injection isolation may use elements such as fluorine, nitrogen, boron, or the like. The isolation layer 113 has an isolation depth beyond hole blocking layer 104.

FIG. 2 illustrates basic principles of the device suppressing current collapse effects and substrate-induced crosstalk effects. When the gate 109 and source 107 are positively biased, holes are injected from the hole injection layer 110 into the hole blocking layer 104, and the injected holes are blocked by the hole blocking layer 104. Meanwhile, the holes will spread along the hole blocking layer 104, forming a conductive hole spreading channel 111 above the hole blocking layer 104. Negative charges in the buffer layer 105 are effectively screened by the mobile holes in the conductive hole spreading channel 111. Moreover, the hole spreading channel 111 can also screen modulation effects of substrate bias on two-dimensional electron gas, thereby achieving suppression of the substrate-induced crosstalk effects. The isolation layer 113 has an isolation depth beyond hole blocking layer 104, which is enable to divide the hole blocking layer 104 and hole spreading layer 111 between different devices.

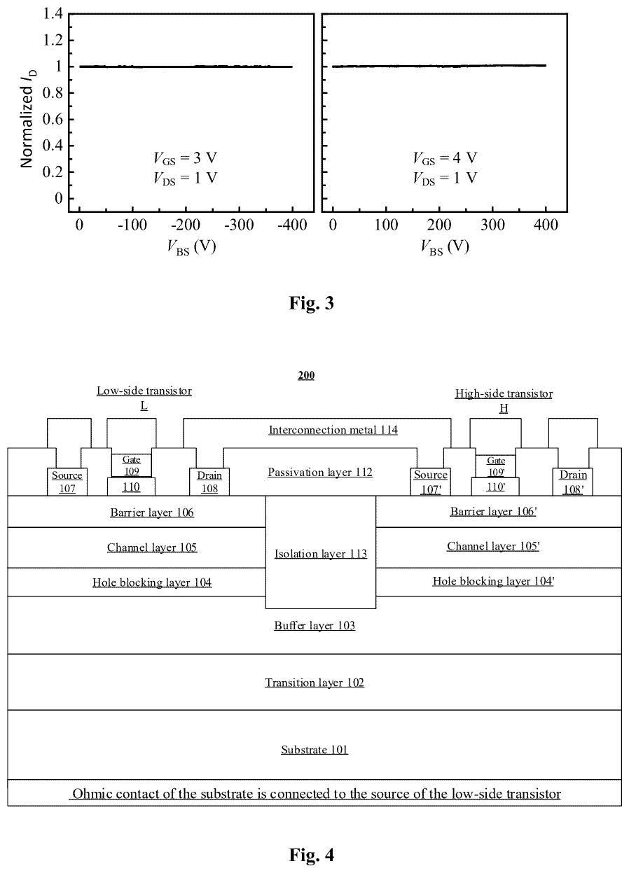

FIG. 3 illustrates test results of conduction characteristics of the GaN device as a function of a substrate voltage. In a traditional GaN device, current characteristics of the device varies with a change in a substrate voltage (V_{BS}). However, according to the GaN device of the present disclosure, in a case where V_{GS}=3V and the substrate voltage V_{BS} is swept from 0V to −400V, conduction characteristics of the device are not affected at all, indicating that the GaN device of the present disclosure provides strong suppression of negative substrate bias effects; in a case where V_{GS}=4V and the substrate voltage V_{BS} is swept from 0V to +400V, conduction characteristics of the device also do not change, indicating that the GaN device of the present disclosure provides strong suppression of positive substrate bias effects and current collapse effects.

FIG. 4 is a two-dimensional cross-sectional view of a GaN bridge integrated circuit according to an embodiment of the present disclosure. As shown in FIG. 4, the GaN bridge integrated circuit 200 includes: two GaN transistors that share a common substrate, one of which serves as a high-side transistor H and the other serves as a low-side transistor L. Each of the upper transistor and the low-side transistor includes a transition layer 102, a buffer layer 103, a hole blocking layer 104, a channel layer 105, and a barrier layer 106 sequentially stacked on the substrate 101. A source 107, 107′ and a drain 108, 108′ of the GaN transistor L, H disposed in an active region above the barrier layer 106, 106′. A gate 109, 109′ of the GaN transistor L, H located between the source 107, 107′ and the drain 108, 108′. A hole injection layer 110, 110′ formed between the gate 109, 109′ and the barrier layer 109, 109′, wherein the hole blocking layer 104, 104′ is inserted between the channel layer 105, 105′ and the buffer layer 103 and the top of a valence band of the hole barrier layer 104, 104′ is lower than the top of a valence band of the channel layer 105, 105′. The source 107′ of the high-side transistor H is connected to the drain 108 of the low-side transistor L, wherein the substrate 101 includes an ohmic contact located on the back of the substrate 101 and connected to the source 107 of the low-side transistor L. Negative substrate bias effects on the high-side transistor H can be suppressed by the GaN devices according to the present disclosure, thereby achieving a GaN bridge integrated circuit with lower conductive resistance, lower loss and higher operating frequency and efficiency. A passivation layer 112 is located between the drain 108 of the low-side transistor L and the source 107′ of the high-side transistor. An Isolation layer 113 separates the hole blocking layer 104, the channel layer 105 and the barrier layer 106 of the low-side transistor L and the hole blocking layer 104', the channel layer 105′ and the barrier layer 106′ of the high-side transistor H. Interconnection metal 114 is connected with the drain 108 of the low-side transistor L and the source 107′ of the high-side transistor and may be any type of conductive metal.

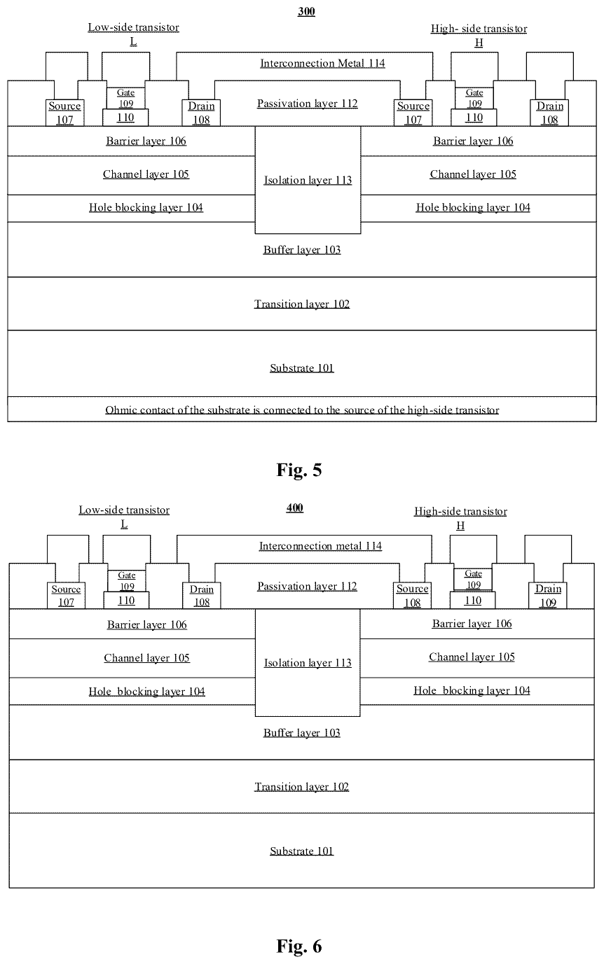

FIG. 5 is a two-dimensional cross-sectional view of a GaN bridge integrated circuit according to an embodiment of the present disclosure. As shown in FIG. 5, the GaN bridge integrated circuit 300 includes: two GaN transistors that share a common substrate, one of which serves as a high-side transistor H and the other serves as a low-side transistor L. Each of the upper transistor and the low-side transistor includes a transition layer 102, a buffer layer 103, a hole blocking layer 104, a channel layer 105, and a barrier layer 106 sequentially stacked on the substrate 101. A source 107, 107′ and a drain 108, 108′ of the GaN transistor L, H disposed in an active region above the barrier layer 106, 106′. A gate 109, 109′ of the GaN transistor L, H located between the source 107, 107′ and the drain 108, 108′. A hole injection layer 110, 110′ formed between the gate 109, 109′ and the barrier layer 109, 109′, wherein the hole blocking layer 104, 104′ is inserted between the channel layer 105, 105′ and the buffer layer 103 and the top of a valence band of the hole barrier layer 104, 104′ is lower than the top of a valence band of the channel layer 105, 105′. The source 107′ of the high-side transistor H is connected to the drain 108 of the low-side transistor L, the substrate 101 includes an ohmic contact located on the back of the substrate 101 and connected to the source 107′ of the high-side transistor H. Positive substrate bias effects on the low-side transistor L can be suppressed by the GaN device according to the present disclosure, thereby achieving a GaN bridge integrated circuit with lower conductive resistance, lower loss and higher operating frequency and efficiency. A passivation layer 112 is located between the drain 108 of the low-side transistor L and the source 107′ of the high-side transistor. An Isolation layer 113 separates the hole blocking layer 104, the channel layer 105 and the barrier layer 106 of the low-side transistor L and the hole blocking layer 104′, the channel layer 105′ and the barrier layer 106′ of the high-side transistor H. Interconnection metal 114 is connected with the drain 108 of the low-side transistor L and the source 107′ of the high-side transistor and may be any type of conductive metal.

FIG. 6 is a two-dimensional cross-sectional view of a GaN bridge integrated circuit according to an embodiment of the present disclosure. As shown in FIG. 6, the GaN bridge integrated circuit 400 includes: two GaN transistors that share a common substrate, one of which serves as a high-side transistor H and the other serves as a low-side transistor L. Each of the upper transistor and the low-side transistor includes a transition layer 102, a buffer layer 103, a hole blocking layer 104, a channel layer 105, and a barrier layer 106 sequentially stacked on the substrate 101. A source 107, 107′ and a drain 108, 108′ of the GaN transistor L, H disposed in an active region above the barrier layer 106, 106′. A gate 109, 109′ of the GaN transistor L, H located between the source 107, 107′ and the drain 108, 108′. A hole injection layer 110, 110′ formed between the gate 109, 109′ and the barrier layer 109, 109′, wherein the hole blocking layer 104, 104′ is inserted between the channel layer 105, 105′ and the buffer layer 103 and the top of a valence band of the hole barrier layer 104, 104′ is lower than the top of a valence band of the channel layer 105, 105′. The source 107′ of the high-side transistor H is connected to the drain 108 of the low-side transistor L, and the substrate 101 is floating. Both positive substrate bias effects on the low-side transistor and negative substrate bias effects on the high-side transistor can be suppressed by the GaN device according to the present disclosure, thereby achieving a GaN bridge integrated circuit with lower conductive resistance, lower loss and higher operating frequency and efficiency. A passivation layer 112 is located between the drain 108 of the low-side transistor L and the source 107′ of the high-side transistor. An Isolation layer 113 separates the hole blocking layer 104, the channel layer 105 and the barrier layer 106 of the low-side transistor L and the hole blocking layer 104′, the channel layer 105′ and the barrier layer 106′ of the high-side transistor H. Interconnection metal 114 is connected with the drain 108 of the low-side transistor L and the source 107′ of the high-side transistor and may be any type of conductive metal.

The GaN device including the hole blocking layer and thus the hole spreading layer according to the present disclosure can effectively suppress the current collapse effects and the substrate-induced crosstalk effects, thereby achieving a GaN device with higher dynamic stability and lower dynamic conduction resistance. The GaN bridge circuit integrated circuit according to the present disclosure can effectively reduce parasitic effects during device interconnection and improve the operating frequency and efficiency of the GaN circuit, and the substrate-induced crosstalk effects in the integration platform can further be suppressed by way of the conductive hole spreading layer.

The above descriptions are merely the preferred embodiments of the present invention and are not used for limiting the present application, and various modifications and variations may be made to the present application for those skilled in the art. Any modification, equivalent replacement and improvement made within the gist and principle of the present application shall fall within the protection scope of the present application.

What is claimed is:

1. A GaN device, comprising:
a substrate; and
a transition layer, a buffer layer, a hole blocking layer, a channel layer, and a barrier layer sequentially stacked on the substrate;
a source and a drain of the GaN device disposed in an active region above the barrier layer;
a gate of the GaN device located between the source and the drain; and
a hole injection layer formed between the gate and the barrier layer,
wherein the hole blocking layer is inserted between the channel layer and the buffer layer and the top of a valence band of the hole barrier layer is lower than the top of a valence band of the channel layer.

2. The GaN device as claimed in claim 1, wherein the hole blocking layer comprises a material selected from one or more of AlGaN, AlN, InN, or AlInGaN.

3. The GaN device as claimed in claim 1, wherein a thickness of the hole blocking layer ranges from 1 nm to 100 nm.

4. The GaN device as claimed in claim 1, wherein a thickness of the hole blocking layer ranges from 15 nm to 25 nm.

5. The GaN device as claimed in claim 1, wherein the hole injection layer is a P-type doped semiconductor.

6. A GaN bridge integrated circuit, comprising:
two GaN transistors that share a common substrate, one of which serves as an upper transistor and the other serves as a low-side transistor, wherein a source of the upper transistor is connected to a drain of the lower transistor,
wherein the substrate is configured by one of the followings:
being floating,
including an ohmic contact located on the back of the substrate and connected to a source of the low-side transistor, or
including an ohmic contact located on the back of the substrate and connected to the source of the upper transistor, and
wherein each of the upper transistor and the low-side transistor comprises:
a transition layer, a buffer layer, a hole blocking layer, a channel layer, and a barrier layer sequentially stacked on the substrate;
a source and a drain of the GaN transistor disposed in an active region above the barrier layer;
a gate of the GaN transistor located between the source and the drain; and
a hole injection layer formed between the gate and the barrier layer,
wherein the hole blocking layer is inserted between the channel layer and the buffer layer and the top of a valence band of the hole barrier layer is lower than the top of a valence band of the channel layer.

7. The GaN bridge integrated circuit as claimed in claim 6, wherein the hole injection layer is a P-type doped semiconductor.

8. The GaN bridge integrated circuit as claimed in claim 6, wherein the hole blocking layer comprises a material selected from one or more of AlGaN, AlN, InN, or AlInGaN.

9. The GaN bridge integrated circuit as claimed in claim 6, wherein a thickness of the hole blocking layer ranges from 1 nm to 100 nm.

10. The GaN bridge integrated circuit as claimed in claim 6, wherein a thickness of the hole blocking layer ranges from 15 nm to 25 nm.
